(19) United States
(12) Patent Application Publication
(10) Pub. No.: US 2026/0314086 A1
(43) Pub. Date: Oct. 8, 2026

(54) SENSOR MANUFACTURING METHOD AND SENSOR

(71) Applicant: THE HONG KONG UNIVERSITY OF SCIENCE AND TECHNOLOGY, HONGKONG (CN)

(72) Inventors: ZHENGTANG LUO, HONGKONG (CN); YUNXIA HU, HONGKONG (CN)

(21) Appl. No.: 19/169,294

(22) Filed: Apr. 3, 2025

(51) Int. Cl. H10F 39/00; H10F 30/221

(52) U.S. Cl. CPC H10F 39/024; H10F 30/221; H10F 39/811

(57) ABSTRACT

A sensor manufacturing method and a sensor. The manufacturing method includes forming a 2H-MoTe₂ film by telluriding a metal molybdenum film on a first substrate, and preparing a 1T′-MoTe₂ film on one side of the 2H-MoTe₂ film away from the first substrate to form a 1T′-MoTe₂/2H-MoTe₂ homojunction film; etching the 1T′-MoTe₂/2H-MoTe₂ homojunction film to form a patterned structure which comprises a channel layer of a sensor, and preparing a bottom electrode and a first electrode; separating the patterned structure from the first substrate; connecting the bottom electrode with a bottom side of the patterned structure; and connecting the first electrode with a top side of the patterned structure to form the sensor. The method can form a sensor with vertical structure, so that the illumination area is expanded while the channel length is shortened, and the photoresponse is improved.

### TECHNICAL FIELD

The present application relates to the technical field of sensors, and particularly the present application relates to a sensor manufacturing method and a sensor.

### BACKGROUND

The sensor (or transducer) is a detection device that can sense the measured information and can transform the sensed information into an electrical signal or other required forms of information output according to a certain rule to satisfy the requirements of information transmission, processing, storage, display, recording and control. The sensor has penetrated into extremely broad fields such as industrial production, space development, ocean exploration, environmental protection, resource investigation, medical diagnosis, bioengineering, and even preservation of cultural relics. It can be said that from the vast space to the vast ocean and even a variety of complex engineering systems, almost every modernization project is inseparable from various sensors.

In the existing sensors, a class of sensors realizes signal acquisition by converting optical signals into electrical signals. Most of these sensors adopt the transverse device structure with electrodes on the same side of channel materials to achieve photoelectric conversion and signal output. However, this structure correlates the channel length with the illumination area, which makes it difficult to increase the illumination area when the channel length is shortened, thereby reducing the photoresponse of the sensor.

### SUMMARY

With respect to the disadvantages of the existing mode, the present application proposes a sensor manufacturing method and a sensor, which can solve the problem that the existing sensor is affected by the shortening of channel length and the enlargement of illumination area and the use of photoresponse of the sensor is reduced.

According to one aspect of embodiments of the present application, the embodiments of the present application provide a sensor manufacturing method which comprises:
forming a 2H-MoTe₂ film by telluriding a metal molybdenum film on a first substrate, and preparing a 1T′-MoTe₂ film on one side of the 2H-MoTe₂ film away from the first substrate to form a 1T′-MoTe₂/2H-MoTe₂ homojunction film;
etching the 1T′-MoTe₂/2H-MoTe₂ homojunction film to form a patterned structure, and preparing a bottom electrode and a first electrode, wherein the patterned structure comprises a channel layer of a sensor;
separating the patterned structure from the first substrate; connecting the bottom electrode with a bottom side of the patterned structure; connecting the first electrode with a top side of the patterned structure to form the sensor; forming ohmic contact by the top electrode formed by 1T′-MoTe₂ in the patterned structure with 2H-MoTe₂; and forming Schottky contact by the bottom electrode with 2H-MoTe₂ in the patterned structure.

In a possible realization mode, forming a 2H-MoTe₂ film by telluriding a metal molybdenum film on a first substrate comprises:
forming a first metal molybdenum film on the first substrate, heating the first metal molybdenum film under a mixed air flow environment, and blowing the vapor of tellurium powder into the first metal molybdenum film to form the 2H-MoTe₂ film, wherein the mixed air flow environment is formed by hydrogen and argon.

In a possible realization mode, heating the first metal molybdenum film under a mixed air flow environment and blowing the vapor of tellurium powder into the first metal molybdenum film to form the 2H-MoTe₂ film comprises:
placing the first metal molybdenum film into a heating center region of a horizontal tube furnace, blowing the vapor formed after heating a first preset mass of tellurium powder to the metal molybdenum film by mixed air flow, and heating a reaction system corresponding to the 2H-MoTe₂ film to a first preset temperature range under the mixed air flow environment for first preset time to form the 2H-MoTe₂ film.

In a possible realization mode, etching the 1T′-MoTe₂/2H-MoTe₂ homojunction film to form a patterned structure comprises:
preparing a first mask plate on the 1T′-MoTe₂/2H-MoTe₂ homojunction film, and etching the 1T′-MoTe₂/2H-MoTe₂ homojunction film by using the first mask plate to form the patterned structure, wherein in the patterned structure, the 1T′-MoTe₂ film and the 2H-MoTe₂ film have the same pattern.

In a possible realization mode, preparing a bottom electrode and a first electrode comprises:
preparing a second mask plate on a second substrate, depositing metal on one side of the second substrate in which the second mask plate is arranged, removing the second mask plate to form a strip-shaped bottom electrode and a strip-shaped first electrode, and forming the bottom electrode and the first electrode on different second substrates.

In a possible realization mode, the arrangement direction of the bottom electrode at the bottom of the patterned structure crosses the arrangement direction of the first electrode at the top of the patterned structure.

In a possible realization mode, separating the patterned structure from the first substrate and connecting the bottom electrode with a bottom side of the patterned structure comprises:
coating the patterned structure with polymethyl methacrylate (PMMA), solidifying the PMMA and separating the patterned structure from the first substrate in water;
taking out the patterned structure from the water by the bottom electrode, and removing the PMMA on the patterned structure by acetone.

According to one aspect of the embodiments of the present application, a sensor is provided; the sensor comprises at least one pixel unit; the pixel unit comprises a first electrode, a patterned structure formed by a 1T′-MoTe₂/2H-MoTe₂ homojunction film and a bottom electrode arranged sequentially from top to bottom; and the sensor is formed by the above method.

In a possible realization mode, the first electrode crosses the bottom electrode, and each of the first electrode and the bottom electrode is connected with at least one patterned structure.

In a possible realization mode, the first electrode and the bottom electrode have the same structure; the bottom electrode comprises a connecting part and a contact part; the connecting part is arranged in parallel to the bottom of the patterned structure; the contact part is arranged on one side of the patterned structure; and each connecting part is connected with at least one patterned structure.

The technical solutions provided in the embodiments of the present application bring the following beneficial technical effects:

The sensor manufacturing method provided by the present application has the following beneficial effects. The 2H-MoTe₂ film is formed by telluriding the metal molybdenum film on the first substrate, and the 1T′-MoTe₂ film is prepared on one side of the 2H-MoTe₂ film away from the first substrate to form the 1T′-MoTe₂/2H-MoTe₂ homojunction film. The 1T′-MoTe₂/2H-MoTe₂ homojunction film is etched to form the patterned structure, and the bottom electrode and the first electrode are prepared. The patterned structure is separated from the first substrate; the bottom electrode is connected with the bottom side of the patterned structure; the first electrode is connected with the top side of the patterned structure to form the sensor; the top electrode formed by 1T′-MoTe₂ in the patterned structure forms ohmic contact with 2H-MoTe₂; and the bottom electrode forms Schottky contact with 2H-MoTe₂ in the patterned structure. The present application can form a sensor with vertical structure, so that the illumination area can be expanded while the channel length is shortened, and the photoresponse can be improved. Moreover, the structure of each unit in the sensor is simple, which effectively improves the advantages of the sensor in integration.

Appended aspects and advantages of the present application will be partially supplied in the following description, and will become apparent from the following description, or will be known through the practice of the present application.

### DESCRIPTION OF DRAWINGS

Above and/or appended aspects and advantages of the present application will become apparent and easy to understand from the following description of the embodiments in combination with the drawings, wherein

FIG. 1 is a flow chart of a sensor manufacturing method provided in an embodiment of the present application;

FIG. 2 is a top view of a sensor provided in an embodiment of the present application;

FIG. 3 is an exploded diagram of a sensor provided in an embodiment of the present application;

FIG. 4 is a front view of a sensor provided in an embodiment of the present application;

FIG. 5 is a right view of a sensor provided in an embodiment of the present application;

FIG. 6 is a structural diagram of a bottom electrode provided in an embodiment of the present application.

### DESCRIPTION OF DRAWING NUMBERS

1 first substrate; 2 bottom electrode; 21 contact part; 22 connecting part; 3 patterned structure; 31 2H-MoTe₂ film; 32 1T′-MoTe₂ film; 4 first electrode.

### DETAILED DESCRIPTION

The embodiments of the present application will be described below in combination with the drawings in the present application. It shall be understood that the embodiments illustrated below in combination with the drawings are illustrative description for explaining the technical solutions of the embodiments of the present application, and do not constitute limitations on the technical solutions of the embodiments of the present application.

Those skilled in the art shall understand that unless specifically stated, “said” and “the” used herein may also include the plural form. It shall be further understood that the term “comprise” used in the description of the present application refers to the existence of the features, integers, steps, operation, elements and/or assemblies, but does not exclude other features, information, data, steps, operation, elements, assemblies and/or combinations thereof implemented supported by the technical field. It shall be understood that when one element is “connected” or “coupled” to another element, the element can be directly connected or coupled to another element, or it can mean that a connection relationship is established between the element and another element through an intermediate element. In addition, the “connection” or “coupling” used herein may include wireless connection or a wireless coupling. The term “and/or” used herein refers to at least one of items limited by the term. For example, “A and/or B” may be realized as “A”, or realized as “B”, or realized as “A and B”.

To make the purpose, the technical solutions and the advantages of the present application more clear, the embodiments of the present application will be further described below in detail in combination with the drawings.

The embodiments of the present application provide a sensor manufacturing method. A sensor manufactured by the method can be an image sensor, a photoelectric sensor and other sensors capable of generating electrical signals based on illuminated light signals.

Description is made by taking a self-powered image sensor as an example below.

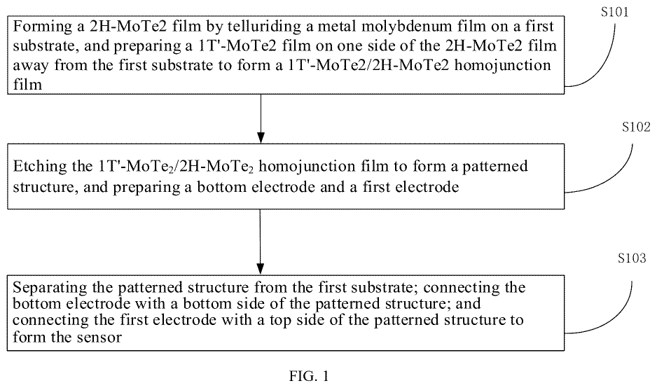

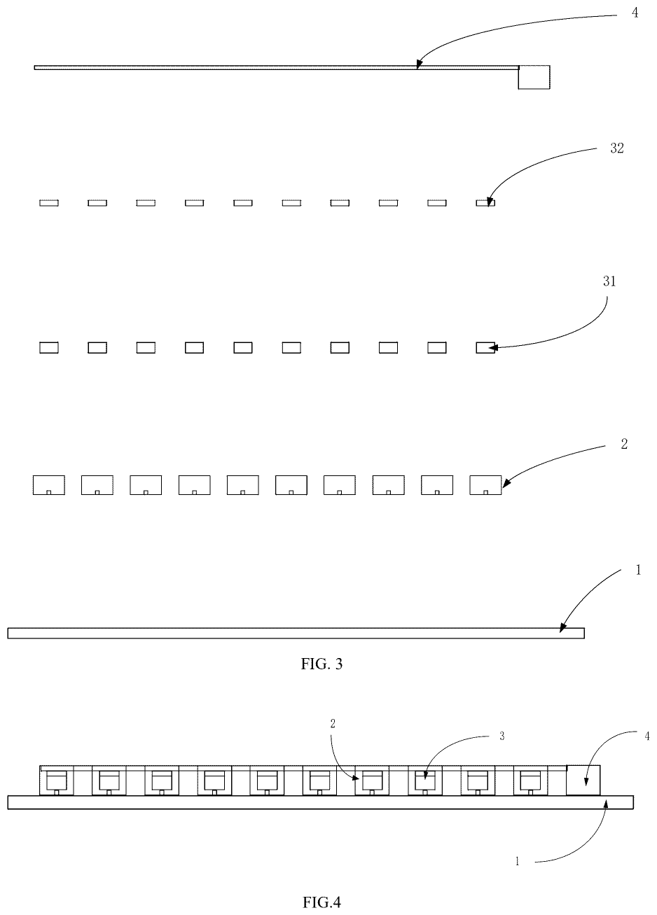

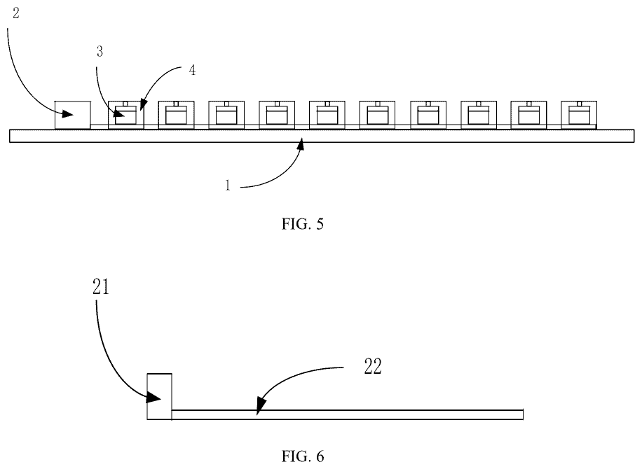

As shown in FIG. 1 to FIG. 6, the sensor manufacturing method of the present application comprises:

S101: forming a 2H-MoTe₂ (molybdenum ditelluride with semiconductor phase and hexagonal lattice) film by telluriding a metal molybdenum film on a first substrate 1, and preparing a 1T′-MoTe₂ (molybdenum ditelluride with metallic phase and monoclinic lattice) film on one side of the 2H-MoTe₂ film 31 away from the first substrate 1 to form a 1T′-MoTe₂/2H-MoTe₂ homojunction film.

Optionally, the first substrate 1 can be a sapphire substrate, or can be made of dielectric material such as aluminum oxide, hafnium dioxide or silicon dioxide to adapt to different sensor application needs.

Optionally, forming a 2H-MoTe₂ film 31 by a metal molybdenum film on a first substrate 1 comprises: forming a first metal molybdenum film on the first substrate 1, heating the first metal molybdenum film under a mixed air flow environment, and blowing the vapor of tellurium powder into the first metal molybdenum film to form the 2H-MoTe₂ film 31, wherein the mixed air flow environment is formed by hydrogen and argon.

Optionally, the metal molybdenum film can be formed on the first substrate 1 by a magnetron sputtering technology, and the thickness of the metal molybdenum film corresponds to the thickness of the 2H-MoTe₂ film 31.

In one embodiment, the first substrate 1 can be a sapphire substrate, and the metal molybdenum film is sputtered on the sapphire substrate by magnetron sputtering (the power of the magnetron sputtering can be 100 W). The thickness of the metal molybdenum film can be 1 nm-200 nm, and the thickness of the 2H-MoTe₂ film 31 can be regulated and controlled by adjusting the thickness of the metal molybdenum film. The size of the first substrate 1 can be 1 cm*1 cm.

Optionally, heating the first metal molybdenum film under a mixed air flow environment and blowing the vapor of tellurium powder into the first metal molybdenum film to form the 2H-MoTe₂ film 31 comprises: placing the first metal molybdenum film into a heating center region of a horizontal tube furnace, blowing the vapor formed after heating a first preset mass of tellurium powder to the metal molybdenum film by mixed air flow, and heating a reaction system corresponding to the 2H-MoTe₂ film 31 to a first preset temperature range under the mixed air flow environment for first preset time to form the 2H-MoTe₂ film 31.

Optionally, the tellurium powder is high-purity tellurium powder and the purity is greater than or equal to 99.99%; and the tellurium powder is placed upstream of the mixed air flow corresponding to the position of the first metal molybdenum film, so as to use the mixed air flow to bring the vapor formed by heating the tellurium powder to the first metal molybdenum film. The first preset mass can be 1.0-2.0 g, the first preset time can be 150 minutes, and the first preset temperature range can be 630-720° C., preferably 680° C.

In one embodiment, after the first metal molybdenum film is prepared, the first metal molybdenum film is placed in the heating center region of the horizontal tube furnace, and 1.0-2.0 g of high-purity tellurium powder (purity ≥99.99%) is placed upstream of the mixed air flow direction compared to the position of the first metal molybdenum film in the horizontal tube furnace. In the mixed air flow environment of hydrogen (H₂) and argon (Ar), the reaction system (the region where the first metal molybdenum film is located in the horizontal tube furnace) is heated to 630-720° C., and maintained for 150 minutes, and finally the 2H-MoTe₂ film is prepared.

Alternatively, the preparation mode of the 1T′-MoTe₂ film 32 is the same as that of the 2H-MoTe₂ film 31, which uses chemical vapor deposition for preparation.

In one embodiment, metal molybdenum is sputtered on the 2H-MoTe₂ film 31 by a magnetron sputtering technology to form a second metal molybdenum film, and the thickness of the second metal molybdenum film corresponds to the thickness of the 1T′-MoTe₂ film 32. Then, the second metal molybdenum film is placed in the heating center region of the horizontal tube furnace (the first substrate 1 is kept in the heating center region), and 50-200 mg of high-purity tellurium powder (purity ≥99.99%) is placed upstream of the air flow direction of the position of the second metal molybdenum film in the horizontal tube furnace. Under the mixed air flow environment of H₂ and Ar, the reaction system is heated to 450-550° C., preferably 500° C., and maintained for 5 minutes. Finally, the 1T′-MoTe₂ 32 is prepared on the 2H-MoTe₂ film 31. Thus, the 1T′-MoTe₂/2H-MoTe₂ homojunction film is synthesized.

Optionally, the sensor has atomically adjustable channel length by adjusting the thickness of the 2H-MoTe₂ film when the sensor is manufactured.

S102: etching the 1T′-MoTe₂/2H-MoTe₂ homojunction film to form a patterned structure 3, and preparing a bottom electrode 2 and a first electrode 4.

Optionally, when the sensor is a self-driven image sensor, the patterned structure 3 can form a channel layer of the pixel unit in the self-driven image sensor through the 2H-MoTe₂ in the structure, and photoelectric conversion is realized through the channel layer. The material of the channel layer can also be a transition metal chalcogenide, a transition metal main group compound, a metal oxide or black phosphorus with photoelectric conversion characteristics to achieve different photoelectric characteristics.

Optionally, etching the 1T′-MoTe₂/2H-MoTe₂ homojunction film to form a patterned structure 3 comprises: preparing a first mask plate on the 1T′-MoTe₂/2H-MoTe₂ homojunction film, and etching the 1T′-MoTe₂/2H-MoTe₂ homojunction film by using the first mask plate to form the patterned structure 3. In the patterned structure 3, the 1T′-MoTe₂ film 32 and the 2H-MoTe₂ film 31 have the same pattern.

Optionally, the first mask plate can be prepared by a standard ultraviolet lithography technology and other mask plate preparation technologies, and is a photoresist mask plate. Specifically, the first mask plate can be a regular shape such as a square and a triangle, or an irregular shape, and the shape can be determined according to the shape of the patterned structure 3.

In one embodiment, a photoresist mask plate with a 10×10 square pattern (the side length of the square pattern is 20-600 μm) is prepared on the 1T′-MoTe₂/2H-MoTe₂ homojunction film by the standard ultraviolet lithography.

Optionally, the 1T′-MoTe₂/2H-MoTe₂ homojunction film having the first mask plate on the surface is etched by using a reactive ion etching (RIE) technology. The etching gas used is sulfur hexafluoride (SF₆); the 1T′-MoTe₂/2H-MoTe₂ homojunction that is not covered by the photoresist on the first mask plate is etched; and then the photoresist is removed with acetone to construct a 10×10 square 1T′-MoTe₂/2H-MoTe₂ homojunction array (with the same pattern as that formed by etching the 1T′-MoTe₂ film 32 and the 2H-MoTe₂ film 31).

Optionally, the length, the width and the thickness of the channel layer formed by the patterned structure 3 can be selected from 10 nm to 500 μm, from 10 nm to 500 μm and from 0.6 nm to 200 nm to satisfy different design needs.

Optionally, preparing a bottom electrode 2 and a first electrode 4 comprises: preparing a second mask plate on a second substrate, depositing metal on one side of the second substrate in which the second mask plate is arranged, removing the second mask plate to form a strip-shaped bottom electrode 2 and a strip-shaped first electrode 4, and forming the bottom electrode 2 and the first electrode 4 on different second substrates. The strip-shaped structures of the bottom electrode 2 and the first electrode 4 can effectively reduce the number of electrodes required by the sensor, thereby greatly simplifying the preparation technology and the integration of the sensor.

Optionally, the material of the bottom electrode 2 and the first electrode 4 can be independently selected as conductive metal, conductive metal oxide, graphene or conductive van der Waals material to improve the electrical conductivity of the device, wherein the materials used for the first electrode 4 and the bottom electrode 2 can be different or the same.

Optionally, the material used for the second substrate can be the same as that of the first substrate 1; and the metal can be deposited on the second substrate by using the magnetron sputtering technology. After the metal is deposited, the second mask plate is removed to obtain the bottom electrode 2 and the first electrode 4. Wherein the formation mode of the second mask plate can be the same as that of the first mask plate. Specifically, the standard ultraviolet lithography technology can be used to prepare the second mask plate.

Optionally, the shapes of the bottom electrode 2 and the first electrode 4 can be the same, wherein the bottom electrode 2 comprises a connecting part 22 and a contact part 21; the connecting part 22 is a strip-shaped structure; the width of the contact part 21 is greater than the width of the connecting part 22; and the height of the contact part 21 can be greater than the thickness of the patterned structure 3.

S103: separating the patterned structure 3 from the first substrate 1; connecting the bottom electrode 2 with a bottom side of the patterned structure 3; and connecting the first electrode 4 with a top side of the patterned structure 3 to form the sensor.

Optionally, the first electrode 4 forms a top electrode with the 1T′-MoTe₂ in the patterned structure 3, the 1T′-MoTe₂ in the patterned structure 3 forms ohmic contact with the 2H-MoTe₂, and the bottom electrode 2 forms Schottky contact with the patterned structure 3. The self-powered photoelectric detection function of the sensor is realized through the modes of ohmic contact and Schottky contact.

Optionally, the arrangement direction of the bottom electrode 2 at the bottom of the patterned structure 3 crosses the arrangement direction of the first electrode 4 at the top of the patterned structure 3.

In one embodiment, the arrangement direction of the bottom electrode 2 is perpendicular to the arrangement direction of the first electrode 4, and the illumination area of the patterned structure 3 connected with the bottom electrode 2 and the first electrode 4 is determined by the cross area of the bottom electrode 2 and the first electrode 4.

Optionally, separating the patterned structure 3 from the first substrate 1 and connecting the bottom electrode 2 with a bottom side of the patterned structure 3 comprises: coating the patterned structure 3 with PMMA, solidifying the PMMA and separating the patterned structure 3 from the first substrate 1 in water; taking out the patterned structure 3 from the water by the bottom electrode 2, and removing the excess PMMA on the patterned structure 3 by acetone. Wherein the patterned structure 3 can also be taken out of the water by the first electrode 4, and the bottom electrode 2 is connected with the patterned structure 3.

Optionally, the connecting mode of the first electrode 4 and the patterned structure 3 is the same as the connecting mode of the bottom electrode 2 and the patterned structure 3.

In one embodiment, the surface of the patterned 1T-MoTe₂/2H-MoTe₂ homojunction array is spin-coated with PMMA, and solidified on a hot platform at 120° C. The homojunction array is separated from the first substrate 1 in water, and the homojunction array is pulled out of the water by using the second substrate with a strip-shaped electrode (the bottom electrode 2). After drying, a strip-shaped motor and the homojunction array are placed in acetone to remove the PMMA polymer on the surface. Then, a strip-shaped metal electrode (the first electrode 4) on another substrate is transferred to the homojunction array by using the same method to construct a top metal electrode of the image sensor.

Optionally, when the sensor is a self-powered image sensor, the bottom electrode 2, the patterned structure 3 and the first electrode 4 constitute each pixel unit in the self-powered image sensor. Compared with the 2H-MoTe₂, the bottom electrode 2 has a higher Fermi level. Thus, electrons are transferred from the bottom electrode 2 to the 2H-MoTe₂ after contact until an equilibrium state. A built-in electric field with a direction from the bottom electrode 2 to the 2H-MoTe₂ is formed at an interface, resulting in the downward bending of the energy band of the 2H-MoTe₂ in contact with the bottom electrode 2. Fermi levels of the 1T′-MoTe₂ and the 2H-MoTe₂ are similar. There is no obvious energy level change after contact, and there is no built-in electric field at the interface. When the 1T′-MoTe₂/2H-MoTe₂ and the bottom electrode 2 in the pixel unit with vertical structure are illuminated by light, electrons in the valence band of the 2H-MoTe₂ are excited to the conduction band, to generate electron-hole pairs. Then, under the influence of the built-in electric field, photogenerated electrons migrate from the 2H-MoTe₂ to one side of the bottom electrode 2, and photogenerated holes are transferred from the 2H-MoTe₂ to the 1T′-MoTe₂, resulting in the generation of photocurrent, so as to realize the optical signal detection.

Optionally, as the thickness of the 2H-MoTe₂ gradually increases, the resistance in the vertical direction of the 2H-MoTe₂ is gradually enhanced, inducing that the current of the sensor at the same voltage gradually decreases. Moreover, as the thickness of the 2H-MoTe₂ gradually increases, the light absorption of the 2H-MoTe₂ layers increases, resulting in the enhanced current of the sensor under illumination. Therefore, as the thickness of 2H-MoTe₂ increases, the current under illumination of this sensor increases at first and then decreases. And the current under illumination reaches the highest value when the thickness at the predetermined thickness (which can be 23 nm).

In one embodiment, when the sensor is a self-powered image sensor, short circuit current (I_{sc}) is positively correlated with light intensity (Pᵢ), and a fitting formula can be I_{sc}∝Pᵢ^{0.88±0.05}, with an index of 0.88±0.05 slightly less than 1. This is because the device needs to undergo the complex processes of generation, recombination and capture of the electron-hole pairs under illumination.

The sensor manufacturing method of the present application has the following advantages:
(1) The photodetector with integrated crossbar array structure is used in the present invention so that a plurality of photodetectors with vertical structures are formed in the sensor, which reduces the structural complexity of the sensor and has great advantages in terms of integration.
(2) The semiconductor 2H-MoTe₂ and the bottom electrode 2 are in Schottky contact, and the semiconductors 2H-MoTe₂ and 1T′-MoTe₂ are in ohmic contact, so that the self-powered photoelectric detection function is realized.
(3) The vertical device structure has large illumination area and atomically adjustable channel length. The highest performance is achieved when the channel length is 23 nm, and the single pixel has high responsivity (4.6 A·W⁻¹) and detectivity (5.8×10¹³ cm·Hz^{1/2} W⁻¹) in near-infrared light (1060 nm) without external bias.
(4) Because the semiconductor 2H-MoTe₂ has a band gap of about 0.8 eV, the image sensor has self-powered imaging capabilities in visible light (520 nm) and near-infrared light (1060 nm).

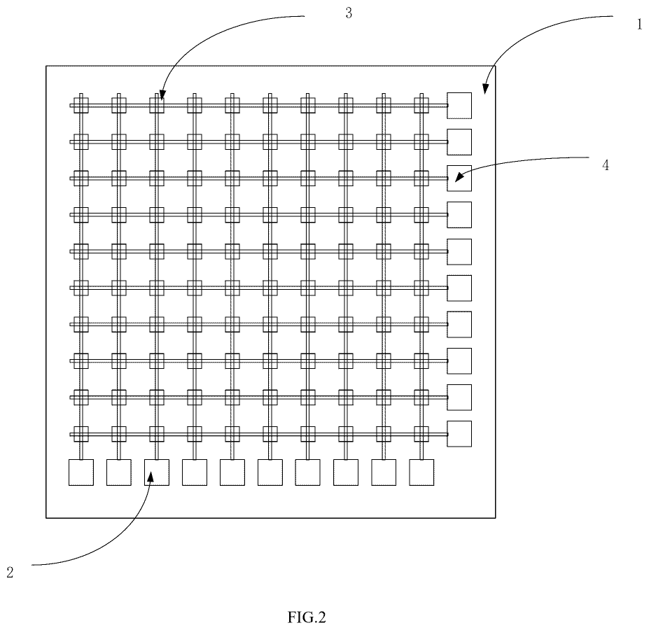

In one optional embodiment, a sensor is provided in combination with the sensor manufacturing method provided in the above embodiments, as shown in FIG. 2 to FIG. 6. The sensor comprises at least one pixel unit; the pixel unit comprises a first electrode 4, a patterned structure 3 formed by a 1T′-MoTe₂/2H-MoTe₂ homojunction film and a bottom electrode 2 arranged sequentially from top to bottom; and the sensor is formed by the method in the above embodiments.

Optionally, the first electrode 4 crosses the bottom electrode 2, and each of the first electrode 4 and the bottom electrode 2 is connected with at least one patterned structure 3.

Optionally, each sensor can be provided with a plurality of first electrodes 4 and a plurality of bottom electrodes 2, and each bottom electrode 2 and each first electrode 4 can be connected with a plurality of patterned structures 3. The patterned structures 3 can be arranged at equal intervals.

In one embodiment, the arrangement direction of the first electrode 4 can be perpendicular to the arrangement direction of the bottom electrode 2.

Optionally, the first electrode 4 and the bottom electrode 2 can have the same structure; the bottom electrode 2 comprises a connecting part 22 and a contact part 21; the connecting part 22 is arranged in parallel to the bottom of the patterned structure 3; the contact part 21 is arranged on one side of the patterned structure 3; and each connecting part 22 is connected with at least one patterned structure 3. Wherein the contact part 21 can be used for transmitting electrical signals generated by the sensor to other devices.

Optionally, the height of the contact part 21 can be greater than the thickness of the patterned structure 3. The heights of the contact parts 21 of the bottom electrode 2 and the first electrode 4 can be the same. In the sensor, the contact parts 21 of the bottom electrode 2 or the first electrode 4 are arranged side by side on the bottom and top surfaces of the sensor.

Those skilled in the art can understand that various operations, methods, steps in processes, measures and solutions discussed in the present application may be alternated, changed, combined or deleted. Further, various operations, methods, other steps in processes, measures and solutions discussed in the present application may also be alternated, changed, rearranged, decomposed, combined or deleted. Further, various operations, methods, steps in processes, measures and solutions disclosed by the present application in related technologies may also be alternated, changed, rearranged, decomposed, combined or deleted.

In the description of the present application, terms “central”, “upper”, “lower”, “front”, “rear”, “left”, “right”, “vertical”, “horizontal”, “top”, “bottom”, “inner”, “outer”, etc. indicate direction or position relationships which are exemplary direction or position relationships shown based on the drawings, and are only intended to facilitate the description or the simplification of the description of the embodiments of the present application rather than to indicate or imply that the indicated device or component must have a specific direction or constructed and operated in a specific direction, and therefore, shall not be understood as a limitation to the present application.

The terms such as “first” and “second” are only used for the purpose of description, rather than being understood to indicate or imply relative importance or hint the number of indicated technical features. Thus, the features limited by “first” and “second” can explicitly or impliedly comprise one or more features. In the description of the present application, the meaning of “a plurality of” is two or more unless otherwise specified.

It should be noted in the description of the present application that, unless otherwise specifically regulated and defined, terms such as “installation”, “connected” and “connection” shall be understood in broad sense, and for example, may refer to fixed connection or detachable connection or integral connection, and may refer to direct connection or indirect connection through an intermediate medium or inner communication of two elements. For those of ordinary skill in the art, the meanings of the above terms in the present application may be understood according to specific conditions.

In the illustration of the description, specific features, structures, materials or characteristics can be combined appropriately in any one or more embodiments or examples.

The above only describes part of the embodiments of the present application. It should be noted that, for those ordinary skilled in the art, on the premise of not deviating from the technical conception of the solution in the present application, other similar implementation means based on the technical idea of the present application also belongs to the protection scope of the embodiments of the present application.

1. A sensor manufacturing method, comprising:
forming a 2H-MoTe₂ film by telluriding a metal molybdenum film on a first substrate, and preparing a 1T′-MoTe₂ film on one side of the 2H-MoTe₂ film away from the first substrate to form a 1T′-MoTe₂/2H-MoTe₂ homojunction film;
etching the 1T′-MoTe₂/2H-MoTe₂ homojunction film to form a patterned structure, and preparing a bottom electrode and a first electrode, wherein the patterned structure comprises a channel layer of a sensor;
separating the patterned structure from the first substrate; connecting the bottom electrode with a bottom side of the patterned structure; connecting the first electrode with a top side of the patterned structure to form the sensor; forming ohmic contact by the top electrode formed by 1T′-MoTe₂ in the patterned structure with 2H-MoTe₂; and forming Schottky contact by the bottom electrode with 2H-MoTe₂ in the patterned structure.

2. The sensor manufacturing method according to claim 1, wherein forming a 2H-MoTe₂ film by telluriding a metal molybdenum film on a first substrate comprises:
forming a first metal molybdenum film on the first substrate, heating the first metal molybdenum film under a mixed air flow environment, and blowing the vapor of tellurium powder into the first metal molybdenum film to form the 2H-MoTe₂ film, wherein the mixed air flow environment is formed by hydrogen and argon.

3. The sensor manufacturing method according to claim 2, wherein heating the first metal molybdenum film under a mixed air flow environment and blowing the vapor of tellurium powder into the first metal molybdenum film to form the 2H-MoTe₂ film comprises:
placing the first metal molybdenum film into a heating center region of a horizontal tube furnace, blowing the vapor formed after heating a first preset mass of tellurium powder to the metal molybdenum film by mixed air flow, and heating a reaction system corresponding to the 2H-MoTe₂ film to a first preset temperature range under the mixed air flow environment for first preset time to form the 2H-MoTed₂ film.

4. The sensor manufacturing method according to claim 1, wherein etching the 1T′-MoTe₂/2H-MoTe₂ homojunction film to form a patterned structure comprises:
preparing a first mask plate on the 1T′-MoTe₂/2H-MoTe₂ homojunction film, and etching the 1T′-MoTe₂/2H-MoTe₂ homojunction film by using the first mask plate to form the patterned structure, wherein in the patterned structure, the 1T′-MoTe₂ film and the 2H-MoTe₂ film have the same pattern.

5. The sensor manufacturing method according to claim 1, wherein preparing a bottom electrode and a first electrode comprises:
preparing a second mask plate on a second substrate, depositing metal on one side of the second substrate in which the second mask plate is arranged, removing the second mask plate to form a strip-shaped bottom electrode and a strip-shaped first electrode, and forming the bottom electrode and the first electrode on different second substrates.

6. The sensor manufacturing method according to claim 5, wherein the arrangement direction of the bottom electrode at the bottom of the patterned structure crosses the arrangement direction of the first electrode at the top of the patterned structure.

7. The sensor manufacturing method according to claim 1, wherein separating the patterned structure from the first substrate and connecting the bottom electrode with a bottom side of the patterned structure comprises:
coating the patterned structure with polymethyl methacrylate (PMMA), solidifying the PMMA and separating the patterned structure from the first substrate in water;
taking out the patterned structure from the water by the bottom electrode, and removing the PMMA on the patterned structure by acetone.

8. A sensor, comprising at least one pixel unit, wherein the pixel unit comprises a first electrode, a patterned structure formed by a 1T′-MoTe₂/2H-MoTe₂ homojunction film and a bottom electrode arranged sequentially from top to bottom; and the sensor is formed by the method according to claim 1.

9. The sensor according to claim 8, wherein the first electrode crosses the bottom electrode, and each of the first electrode and the bottom electrode is connected with at least one patterned structure.

10. The sensor according to claim 8, wherein the first electrode and the bottom electrode have the same structure; the bottom electrode comprises a connecting part and a contact part; the connecting part is arranged in parallel to the bottom of the patterned structure; the contact part is arranged on one side of the patterned structure; and each connecting part is connected with at least one patterned structure.

11. A sensor, comprising at least one pixel unit, wherein the pixel unit comprises a first electrode, a patterned structure formed by a 1T′-MoTe2/2H-MoTe2 homojunction film and a bottom electrode arranged sequentially from top to bottom; and the sensor is formed by the method according to claim 2.

12. The sensor according to claim 11, wherein the first electrode crosses the bottom electrode, and each of the first electrode and the bottom electrode is connected with at least one patterned structure.

13. The sensor according to claim 11, wherein the first electrode and the bottom electrode have the same structure; the bottom electrode comprises a connecting part and a contact part; the connecting part is arranged in parallel to the bottom of the patterned structure; the contact part is arranged on one side of the patterned structure; and each connecting part is connected with at least one patterned structure.

14. A sensor, comprising at least one pixel unit, wherein the pixel unit comprises a first electrode, a patterned structure formed by a 1T′-MoTe2/2H-MoTe2 homojunction film and a bottom electrode arranged sequentially from top to bottom; and the sensor is formed by the method according to claim 3.

15. The sensor according to claim 14, wherein the first electrode crosses the bottom electrode, and each of the first electrode and the bottom electrode is connected with at least one patterned structure.

16. The sensor according to claim 14, wherein the first electrode and the bottom electrode have the same structure; the bottom electrode comprises a connecting part and a contact part; the connecting part is arranged in parallel to the bottom of the patterned structure; the contact part is arranged on one side of the patterned structure; and each connecting part is connected with at least one patterned structure.

17. A sensor, comprising at least one pixel unit, wherein the pixel unit comprises a first electrode, a patterned structure formed by a 1T′-MoTe2/2H-MoTe2 homojunction film and a bottom electrode arranged sequentially from top to bottom; and the sensor is formed by the method according to claim 4.

18. The sensor according to claim 17, wherein the first electrode crosses the bottom electrode, and each of the first electrode and the bottom electrode is connected with at least one patterned structure.

19. The sensor according to claim 17, wherein the first electrode and the bottom electrode have the same structure; the bottom electrode comprises a connecting part and a contact part; the connecting part is arranged in parallel to the bottom of the patterned structure; the contact part is arranged on one side of the patterned structure; and each connecting part is connected with at least one patterned structure.

20. A sensor, comprising at least one pixel unit, wherein the pixel unit comprises a first electrode, a patterned structure formed by a 1T′-MoTe2/2H-MoTe2 homojunction film and a bottom electrode arranged sequentially from top to bottom; and the sensor is formed by the method according to claim 6.
